(19) United States
(12) Patent Application Publication
(10) Pub. No.: US 2005/0082624 A1
(43) Pub. Date: Apr. 21, 2005

(54) Germanate gate dielectrics for semiconductor devices

(76) Inventors: Evgeni Gousev, Mahopac, NY (US); Alessandro Cesare Callegari, Yorktown Heights, NY (US); Dianne L. Lacey, Mahopac, NY (US); Deborah Ann Neumayer, Danbury, CT (US); Huiling Shang, Yorktown Heights, NY (US)

Correspondence Address: George Sai-Halasz, 145 Fernwood Dr., Greenwich, RI, 02818, US

(21) Appl. No.: 10/689,222

(22) Filed: Oct. 20, 2003

(51) Int. Cl. H01L 29/94

(52) U.S. Cl. 257/410

(57) ABSTRACT

A structure, and method of fabrication, for high performance semiconductor field effect devices is disclosed. These devices are having a gate dielectric containing a germanate material. In representative embodiments the gate dielectric is essentially a layer of a germanate material. The chemical composition of such materials is Me_{z}GeₓO_{y}, where Me stands for a metal with high ion polarizability, and x, y, and z are non-zero integers. Such a gate dielectric is advantageous, from the point of view of dielectric constant, barrier height, carrier mobility, thermal stability, and interface stability.

### FIELD OF THE INVENTION

The present invention relates to a new class of gate dielectric materials allowing better device properties and expanded device choice in the deeply submicron, high performance regime. More specifically, the invention teaches gate dielectrics formed with germanate materials.

### BACKGROUND OF THE INVENTION

Today's integrated circuits include a vast number of devices. Smaller devices are key to enhance performance and to improve reliability. As MOSFET (Metal Oxide Semiconductor Field-Effect-Transistor, a name with historic connotations meaning in general an insulated gate Field-Effect-Transistor) devices are being scaled down, the technology becomes more complex and new methods are needed to maintain the expected performance enhancement from one generation of devices to the next.

One of the most important indicators of potential device performance is the carrier mobility. There is great difficulty in keeping carrier mobility high in devices of deeply submicron generations.

Gate dielectrics is one of the main problems for CMOS field effect device scaling. This is true for both conventional silicon devices and more advanced (e.g. Ge, SiGe, GaAs, InGaAs) devices. For Si-based devices, conventional SiO₂-based dielectrics are reaching the limit of their scaling (˜1 nm).

In Ge-based devices, the situation is even more complicated. Up to now, no reliable high-quality gate dielectric has been found. Germanium oxide is of poor quality and is soluble in water. In general binary metal oxides (e.g. ZrO₂, HfO₂) show ˜40% electron mobility degradation when used as gate dielectrics. Another issue with binary oxides is interface instability, i.e. a thin lower-K material (e.g. SiO₂, SiON, or GeON) is present at the interface which is either deliberately grown there before high-K deposition, or formed due to reactions at high temperatures. Such a thin low-K material decreases the overall capacitance of the gate.

### SUMMARY OF THE INVENTION

This invention teaches a new class of gate dielectric materials for semiconductor field effect devices that, preferably, have higher dielectric constants than SiO₂, e.g., above 4. This materials class is germanate, i.e. Me_{z}GeₓO_{y}, where Me stands for a metal with high ion polarizability, such as Hf, Zr, Y, La, Ti, Ta, Gd, Ce, Bi, Dy, Er, Eu, Tb, Pr, Sr, etc., as well as some further metals of group 3, 4 and 5 of the periodic table and lanthanides; and x, y, and z are non-zero integers.

In accordance with the objectives listed above, the present invention describes a system and method for semiconductor field effect devices having a germanate gate dielectric.

It is a further object of the present invention to teach processors which comprise chips containing such a semiconductor field effect device having a germanate gate dielectric.

### BRIEF DESCRIPTION OF THE DRAWINGS

These and other features of the present invention will become apparent from the accompanying detailed description and drawings, wherein:

FIG. 1 shows a schematic cross sectional view of a semiconductor field effect device having a germanate gate dielectric;

FIG. 2 shows a schematic cross sectional view of a semiconductor field effect device having a germanate gate dielectric and an interlayer; and

FIG. 3 shows a symbolic view of a processor containing at least one chip which contains a semiconductor field effect device having a germanate gate dielectric.

### DETAILED DESCRIPTION OF THE INVENTION

FIG. 1 shows a schematic cross sectional view of a semiconductor field effect device 10 having a germanate gate dielectric. The gate dielectric of a germanate material 100 is an insulator separating a conductive gate 110 from a semiconductor body 160.

Germanate materials have a chemical composition of Me_{z}GeₓO_{y}, where x, y, and z are non-zero integers, in a very wide variety of possible combinations. The “Me” stands for a metal with high ion polarizability, resulting in a high dielectric constant for the germanate material. A non-exhaustive list of such metals include: Hf, Zr, Y, La, Ti, Ta, Gd, Ce, Bi, Dy, Er, Eu, Tb, Pr, Sr, etc., as well as some further metals of group 3, 4 and 5 of the periodic table and lanthanides. Metal polarizabilities are known in the art, for instance polarizabilities of various elements is given in the publication: “Dielectric Polarizabilities of ions in oxides and fluorides”, J. of Applied Physics, v. 73, p. 348 (1993). Germanate materials are known in the chemical art with some of their basic material properties listed, for instance in: Spectrochemica Acta, v. 45A p. 721 (1989) by M. T. Vandenborre et al.

Germanates have a number of properties that makes them uniquely suited as gate dielectric in high performance field effect devices.

Germanates, in general, have a high dielectric constant, which means over approximately 4. Depending on the concentration and type of the metal (Me) in the lattice, the typical and preferred dielectric constant range is between about 8 and 40. For instance, Bismuth Germanate Bi₁₂GeO₂₀ has a dielectric constant of 38. In manufacturing the gate dielectric one would choose the germanate material according to the polarizability of the Me, since higher Me polarizability in general leads to higher dielectric constant, although the final selection will depend on tradeoffs with other material properties.

Germanates can have a high barrier, namely exhibiting high resistance, against charge tunneling. As the thickness of gate dielectrics is decreasing in order to increase the gate-to-channel capacitance, resistance against charge tunneling across the gate dielectric becomes an important issue. The quintessential gate dielectric material is SiO₂ (dielectric constant of 3.9) and can serve as a point for comparison. Since the dielectric constant of germanates is larger than that of SiO₂, a germanate layer which has the same capacitance per unit area as a SiO₂ layer, is thicker than the SiO₂ layer. Furthermore, since resistance against tunneling depends exponentially on layer thickness, the germanate layer will tend to be the more charge penetration resistant. Since there is a large variety of germanate to choose from, it is possible to find one which is resistant to both electron and hole charge penetration. In manufacturing the gate dielectric one would choose the germanate material according to the barrier height, since this influences the resistance against charge tunneling. In general, germanate materials with higher barrier heights will be preferred, although the final selection will depend on tradeoffs with other material properties.

Electric charge mobility (or simply carrier mobility) in the channel region 130 of the semiconductor field effect device 10 is one of the most important parameters in determining device performance. It is known that the kind of material chosen as gate dielectric influences the charge mobility in the channel. This influence involves coupling of charge carriers in the device channel and phonons (lattice vibrations) in the gate dielectric material. According to the soft-phonon picture of channel mobility, for instance in: “Effective electron mobility in Si inversion layers in MOS systems with a high-k insulator: The role of remote phonon scattering”, J. of Applied Physics, v. 90 p. 4587 (2001) by M. Fischetti, many high-K materials with low-energy phonon modes show reduced mobility. Since germanates have complex material structure with heavy chemical elements involved, such as the Ge and most Me atoms in consideration, characteristic phonon spectra of germanates is not likely to couple easily to the speeding carriers in the channel, resulting in high carrier mobility in channels where the dielectric is a germanate material. In manufacturing the gate dielectric one would choose the germanate material in accordance with the aim to maximize the carrier mobility, although the final selection will depend on tradeoffs with other material properties.

The depicting of a semiconductor field effect device in FIG. 1 is almost symbolic, in that, although it actually shows an MOS device it is meant to represent any kind of field effect device. The only common denominator of such devices is that the device current is controlled by a gate 110 acting by its field across an insulator, the so called gate dielectric 100. Accordingly, every field effect device has a (at least one) gate, and a gate insulator. This is central for this invention because the teaching of a new class of gate dielectrics impacts every, and all, field effect devices.

FIG. 1 depicts schematically an MOS field effect device, with the source/drain regions 150, device body 160, and channel region 130. The body, can be bulk, as shown on FIG. 1, or it can be a thin film on an insulator. The channel can be a single one, or multiple one, as on double gated, or FINFET devices. The basic material of the device can be of a wide variety. It can be Si the mainstay material of today's electronics. Or more broadly, it can be a so called Si-based material. The body can be a SiGe compound, or consisting of essentially pure Ge. These latter ones are relatively newly emerging technologies, ever more important with the shrinking of device dimensions and operating voltages.

The germanate dielectric gate is especially advantageous for achieving high performance SiGe and Ge devices. When one attempts to use a so called high K material over Si, there usually is a problem with an SiO₂ interfacial layer present at the high-K Si interface due to the preference of Si to oxidize into SiO₂. For Ge-based devices the germanate dielectric solves two problems. First, it is a good stable insulator over a Ge-based material, or Ge, which is hard to find. Secondly, since Ge does not have a stable oxide, such as SiO₂ is for Si, consequently the Ge-based material (or Ge) and germanate interface will be oxide free, and thus will have higher capacitance and better carrier mobility. Such a germanate gate dielectric would be a key element in enabling a good quality highest mobility SiGe, Ge devices.

Germanate materials may be useful for devices made of III-V semiconductor compounds, such as GaAs, InAs, InGaAs, and others. Such III-V devices traditionally lacked a good gate dielectric. Now with a new class of germanate dielectrics these devices too could be made into regular MOS devices.

Since the germanate dielectric in most high performance devices would be in intimate contact (it would interface) with the channel region of the device, the mutual interface properties, such as mutual stability are important considerations in choosing the right germanate. In manufacturing the gate dielectric one would choose the germanate material in accordance with its interface stability, although the final selection will depend on tradeoffs with other material properties.

The germanate gate material 100, in the most general case, can be one component in a compound gate dielectric, either in a layered form, or even as a mixture. In a representative embodiment even for the case of a compound gate dielectric it is common for the germanate material to constitute a layer. In another representative embodiment the gate dielectric is solely a germanate material, namely it consists essentially of the germanate material. For the gate dielectric applications the germanate material layer has preferably a thickness of about between 1.5 nm and 50 nm. These values are dictated by the desire for high capacitance requiring thin layers, and the desire for good material quality and resistance to charge tunneling which prefers thicker layers.

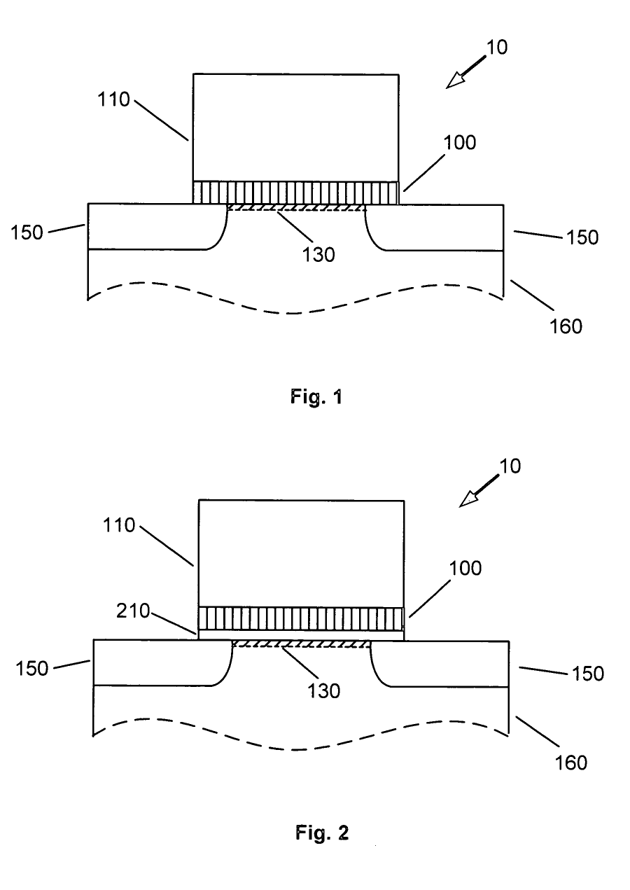

FIG. 2 shows a schematic cross sectional view of an interlayer 210, another representative embodiment of a semiconductor field effect device having a germanate gate dielectric. The gate dielectric includes the interlayer 210 which interfaces with the channel region, and the germanate layer 100 on top of the interlayer 210. An advantage of such interlayers is to provide for a high quality interface with the channel region. They are typically less than approximately 1 nm thick, and comprise materials such as chemical oxides and oxynitrides. Interlayers are taught in U.S. Pat No. 6,444,592 entitled: “Interfacial oxidation process for high-k gate dielectric process integration” to A. Ballantine et al, incorporated herein by reference.

Germanate materials are quite temperature stable, able to withstand temperatures encountered during device fabrication, typically at least 800° C., and possibly close to 1000° C. Because of such temperature stability the standard manufacturing processes of field effect devices can incorporate the use of a germanate material gate dielectric without difficulty. The germanate materials are amenable for both a conventional “gate first” process, and a “gate last” replacement process. In the “gate first” process, the gate dielectric is deposited before the source and drain have been fabricated. In the replacement gate, “gate last” case, fabrication of the source and drain occurs before the gate dielectric is deposited. After deposition, the higher temperature the chosen germanate can tolerate, the more advantageous, and the more options are open in further processing the device. In manufacturing the gate dielectric one would choose the germanate material with high temperature stability, although the final selection will depend on tradeoffs with other material properties.

Germanate materials can be deposited in a wide a variety of ways, such as physical vapor deposition (PVD), sputtering, molecular beam deposition (MBE), metal organic chemical vapor deposition (MOCVD), atomic layer deposition (ALD), and other known techniques. One aspect of the present invention broadly relates to CVD and ALD of germ anates.

In a representative embodiment the Me in the germanate is hafnium. In performing the deposition the hafnium and germanium precursors are composed of the metal bound to at least one ligand selected from the group consisting of hydride, alkyl, alkenyl, cycloalkenyl, aryl, alkyne, carbonyl, amido, imido, hydrazido, phosphido, nitrosyl, nitryl, nitrate, nitrile, halide, azide, alkoxy, siloxy, and/or silyl. The hafnium and germanium precursors may be used neat, or may be dissolved, emulsified or suspended in an inert liquid selected from the group consisting of aliphatic hydrocarbons, aromatic hydrocarbons, alcohols, ethers, aldehydes, ketones, acids, phenols, esters, amines, alkylnitrile, halgonated hydrocarbons, silyated hydrocarbons, thioethers, amines, cyanates, isocyanates, thiocyanates, silicone oils, nitroalkyl, alkylnitrate, and/or mixtures of one or more of the above. A chemical vapor deposition technique or atomic layer deposition technique utilizing the hafnium and germanium precursor to grow films involves vaporizing the precursor, introducing the vaporized precursor into a chemical vapor deposition or atomic layer deposition reactor, and depositing a constituent of the vaporized precursor on a substrate to form a film. Preferred hafnium precursors include hafnium alkoxides, more specifically, hafnium isopropoxide, hafnium sec-butoxide, hafnium ethoxide, hafnium isobutoxide, hafnium methoxide, hafnium propoxide, hafnium butoxide, hafnium tertiary butoxide, or hafnium phenoxide. Preferred germanium precursors include tetraethoxy germanium, tetramethoxy germane, tetramethyl germane, tetraethylgermane, triethylgeramne, diethylgermane, diethyldiethoxygermane, tris(trimethylsilyl)germane, tetrachloride germanium, and germane.

Chemical vapor deposition (CVD) involves introduction of multiple reagents into a reactor simultaneously. Atomic layer deposition (ALD) pertains sequential introduction of multiple reagents into a reactor, including but not limited to atomic layer epitaxy, digital chemical vapor deposition, pulsed chemical vapor deposition and other like methods.

In an exemplary embodiment of hafnium germanate, (Hafnium Germanium Oxide) CVD the following process was used. The hafnium oxide films were deposited in a quartz horizontal hot wall CVD reactor equipped with a 1×3×8″ quartz flow cell. An ATMI (Advanced Technology and Materials, Inc. Danbury, Conn.) LDS 300B liquid delivery system and vaporizer was used to introduce precursors into the reactor. The LDS 300B was retrofitted with a Porter liquid mass flow controller to control the delivery rate of precursors to the reactor. The hafnium precursor was 0.1 moles of hafnium tert-butoxide Hf(t-OC₄H₉)₄ dissolved in 1 liter of octane. The germanium precursor was comprised of 0.1 moles of germanium ethoxide dissolved in 1 liter of octane. The Hafnium to Germanium ratio in the as deposited film was controlled by mixing different ratios of the hafnium and germanium precursor in the LDS 300B. A thin layer (<2 nm) of SiOₓN_{y} layer was deposited on the silicon wafer prior to growth of hafnium germanium oxide. The vaporizer temperature was about 50-150° C., preferably about 120° C. Anhydrous nitrogen was introduced into the vaporizer at about 20-2000 sccm, preferably about 200 sccm as a carrier gas for the volatilized hafnium and germanium precursors. Approximately 1000 sccm of oxygen was introduced through a separate inlet as the reactant gas. The system pressure was about 2 Torr during growth. The substrate was heated by an external high intensity infrared lamp and the susceptor was comprised of Hastalloy. The temperature of the susceptor was monitored by insertion of a thermocouple into the susceptor. Hafnium oxide was deposited at about 300-700° C., preferably at temperatures >400° C.

In an exemplary embodiment of hafnium germanate, (Hafnium Germanium Oxide) ALD the following process was used. In this embodiment, a substrate is placed in a suitable reactor for atomic layer deposition, for example the commercial F-200 reactor made by Microchemistry, and a hafnium oxide film is deposited. Atomic layer deposition is performed in a cyclic fashion with sequential alternating pulses of vaporized hafnium chloride, germanium tetrachloride, water and purge gas.

The reactants were introduced into the ALD reactor according to the following sequence: 1. water, 2. purge, 3. hafnium chloride, 4. purge, 5. water, 6. purge, 7. germanium chloride, 8. purge. The hafnium chloride, germanium chloride and water pulses (steps 1, 3, 5, 7) last about 0.1-1 second, preferably about 0.5 seconds. The inert gas purge pulse (steps 2, 4, 6 and 8) last about 0.2-5 seconds, preferably about 2 seconds. Completion of steps 1-8 is a cycle, the completion of 1 cycle results in deposition of about 0.4-2 monolayer of hafnium germanium oxide or roughly 0.1 nm. For instance, if the preferred thickness of deposited hafnium germanium oxide containing film is 50 nm, approximately 400 cycles of gas switching as described are performed.

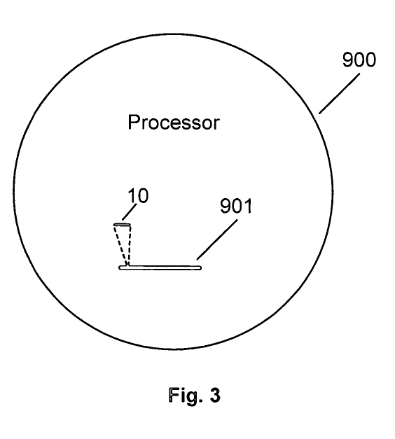

FIG. 3 shows a symbolic view of a processor 900 containing at least one chip which contains a semiconductor field effect device having a germanate gate dielectric. Such a processor has at least one chip 901, which contains at least one field effect device having a germanate gate dielectric 10. The processor 900 can be any processor which can benefit from the germanate gate dielectric field effect device. These devices form part of the processor in their multitude on one or more chips 901. Representative embodiments of processors manufactured with the germanate gate dielectric field effect devices are digital processors, typically found in the central processing complex of computers; mixed digital/analog processors, which benefit significantly from the high mobility of the carriers in the germanate gate dielectric field effect devices; and in general any communication processor, such as modules connecting memories to processors, routers, radar systems, high performance video-telephony, game modules, and others.

Many modifications and variations of the present invention are possible in light of the above teachings, and could be apparent for those skilled in the art. The scope of the invention is defined by the appended claims.

1. A field effect device having a gate dielectric, wherein the gate dielectric comprises a germanate material.

2. The field effect device of claim 1, wherein the germanate material constitutes a layer.

3. The field effect device of claim 2, wherein the germanate material layer has a dielectric constant over 4.

4. The field effect device of claim 3, wherein the germanate material layer has a dielectric constant approximately between 8 and 40.

5. The field effect device of claim 2, wherein the germanate material layer has a thickness of approximately between 1.5 nm and 50 nm.

6. The field effect device of claim 1, further comprising a channel region, wherein the gate dielectric further comprises an interlayer disposed between the channel region and the germanate material layer.

7. The field effect device of claim 6, wherein the interlayer is less than approximately 1 nm thick.

8. The field effect device of claim 1, wherein the gate dielectric consists essentially of the germanate material.

9. The field effect device of claim 1, wherein the gate dielectric comprising the germanate material possesses greater resistance against charge tunneling than a SiO₂ gate dielectric, and a capacitance per unit area of the gate dielectric comprising the germanate material is at least as large as the capacitance per unit area of the SiO₂ gate dielectric.

10. The field effect device of claim 1, wherein the germanate material is hafnium germanium oxide.

11. The field effect device of claim 1, wherein the field effect device is a Si MOS transistor.

12. The field effect device of claim 1, wherein the field effect device is a SiGe-based MOS transistor.

13. The field effect device of claim 1, wherein the field effect device is a Ge MOS transistor.

14. The field effect device of claim 1, wherein the field effect device is a III-V material based MOS transistor.

15. A method for fabricating a semiconductor field effect device comprising the step of:
forming a gate dielectric which comprises a germanate material having a chemical composition of Me_{z}GeₓO_{y}, where Me is a metal, and x, y, and z are non-zero integers.

16. The method of claim 15, further comprising the step of selecting the germanate material to withstand a temperature of at least 800° C.

17. The method of claim 15, further comprising the step of selecting the germanate material in a manner that the gate dielectric has greater resistance against charge tunneling than a SiO₂ gate dielectric, and a capacitance per unit area at least as large as the capacitance per unit area of the SiO₂ gate dielectric.

18. The method of claim 15, further comprising the step of providing a channel region to interface with the germanate material, and selecting the germanate material to provide interface stability with the channel region.

19. The method of claim 15, further comprising the step of providing a channel region to interface with the germanate material, and selecting the germanate material to maximize carrier mobility in the channel region.

20. The method of claim 15, further comprising the step of providing a source and a drain, wherein the step forming the gate dielectric is carried out before the step of providing the source and the drain.

21. The method of claim 15, further comprising the step of providing a source and a drain, wherein the step forming the gate dielectric is carried out after the step of providing the source and the drain.

22. The method of claim 15, wherein the germanate material is formed by a chemical vapor deposition technique.

23. The method of claim 22, wherein the chemical vapor deposition is performed in a temperature range of between about 300° C. and 700° C.

24. The method of claim 15, wherein the germanate material is formed by atomic layer deposition.

25. The method of claim 24, wherein the atomic layer deposition comprises between about 10 and 500 cycles of layer deposition.

26. A processor, comprising:
at least one chip, wherein the chip comprises at least one semiconductor field effect device having a gate dielectric, wherein the gate dielectric comprises a germanate material.

27. The processor of claim 26, wherein the processor is a digital processor.

28. The processor of claim 26, wherein the processor comprises at least one analog circuit.
